(19) United States
(12) Patent Application Publication
(10) Pub. No.: US 2026/0025113 A1
(43) Pub. Date: Jan. 22, 2026

(54) Amplifier Noise Cancellation

(71) Applicant: Apple Inc., Cupertino, CA (US)

(72) Inventors: Masoud Pashaeifar, Munich (DE); Yi Zhao, San Jose, CA (US)

(21) Appl. No.: 18/778,687

(22) Filed: Jul. 19, 2024

(51) Int. Cl. H03F 3/193

(52) U.S. Cl. CPC H03F 3/193; H03F 2200/372; H03F 2200/451

(57) ABSTRACT

Wireless circuitry can include amplifier circuitry. The amplifier circuitry can include a first input transistor having a gate terminal coupled to an input terminal, a second input transistor having a gate terminal coupled to the input terminal, a first inductor coupled to a source terminal of the first input transistor, and a capacitor having a first terminal coupled to the source terminal of the first input transistor and having a second terminal coupled to a source terminal of the second input transistor. The amplifier circuitry can further include a second inductor coupled between the source terminal of the second input transistor and a power supply line. The capacitor can be configured to resonate with the first and second inductors to provide noise cancelling at a target operating frequency.

### FIELD

This disclosure relates generally to electronic devices and, more particularly, to electronic devices with wireless communications circuitry.

### BACKGROUND

Electronic devices can be provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

Radio-frequency signals transmitted by an antenna can be fed through a power amplifier, which is configured to amplify low power analog signals to higher power signals more suitable for transmission through the air over long distances. Radio-frequency signals received at an antenna can be fed through a low noise amplifier, which is configured to amplify low power analog signals to higher power signals for ease of processing at a receiver. It can be challenging to design a satisfactory amplifier for an electronic device.

### SUMMARY

An aspect of the disclosure provides circuitry that includes a first input transistor having a gate terminal coupled to an input terminal, a second input transistor having a gate terminal coupled to the input terminal, a first inductor coupled to a source terminal of the first input transistor, and a capacitor having a first terminal coupled to the source terminal of the first input transistor and having a second terminal coupled to a source terminal of the second input transistor. The circuitry can further include a second inductor coupled between the source terminal of the second input transistor and a power supply line and an input matching network coupled to the input terminal. The circuitry can further include a first transformer having a first primary coil coupled to the first input transistor and a second transformer having a second primary coil coupled to the second input transistor. The capacitor can be configured to resonate with the first and second inductors. The first and second input transistors can have a differential mode source impedance that is based on an inductance of the first inductor or the second inductor and a capacitance of the capacitor and a common mode source impedance that is based on the inductance of the first inductor or the second inductor and not based on the capacitance of the capacitor.

An aspect of the disclosure provides circuitry that includes a first amplifier having a first source degeneration inductor, a second amplifier having a second source degeneration inductor, and a noise cancellation circuit coupled between the first and second source degeneration inductors. The first amplifier can include a first input transistor coupled in series with the first source degeneration inductor; the first input transistor can have a gate terminal coupled to an input terminal; the second amplifier can include a second input transistor coupled in series with the second source degeneration inductor; and the second input transistor can have a gate terminal coupled to the input terminal. The noise cancellation circuit can include a capacitor coupled across a source terminal of the first input transistor and a source terminal of the second input transistor.

An aspect of the disclosure provides amplifier circuitry that includes a first input transistor having a gate terminal coupled to an input terminal, a second input transistor having a gate terminal coupled to the input terminal, a first inductor coupled to a source terminal of the first input transistor, and a second inductor coupled to a source terminal of the second input transistor. The second inductor can be magnetically coupled to the first inductor in accordance with a magnetic coupling coefficient, and the first and second input transistors can exhibit a source impedance that is based on the magnetic coupling coefficient. The magnetic coupling coefficient can be based on an amount of overlap between the first and second inductors. The first inductor can have a first footprint, and the second inductor can have a second footprint that coincides with the first footprint.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having radio-frequency amplifiers in accordance with some embodiments.

FIG. 3 is a diagram of an illustrative amplifier with improved noise cancelling capability in accordance with some embodiments.

FIG. 4 is a diagram of an illustrative amplifier having magnetically coupled source inductors in accordance with some embodiments.

FIG. 5 is a side view showing partially overlapping source inductors in accordance with some embodiments.

FIG. 6 is a side view showing overlapping source inductors in accordance with some embodiments.

FIG. 7 is a plot of noise figure as a function of frequency in accordance with some embodiments.

### DETAILED DESCRIPTION

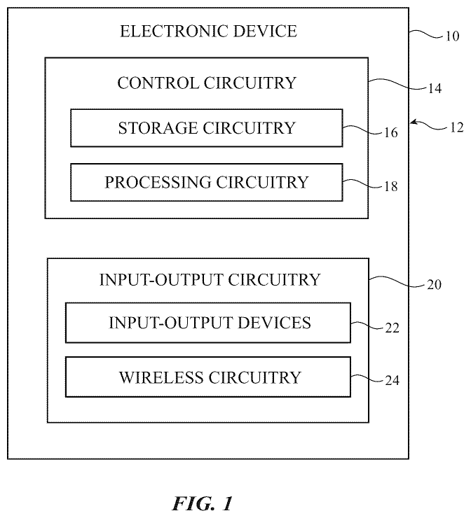

An electronic device such as device 10 of FIG. 1 may be provided with wireless circuitry. The wireless circuitry may include amplifier circuitry such as low noise amplifier (LNA) circuitry configured to amplify signals received via one or more antennas. The amplifier circuitry may include a first amplifier coupled to a quadrature (Q) mixer and having a first input transistor coupled in series with a first source inductor, a second amplifier coupled to an in-phase (I) mixer and having a second input transistor coupled in series with a second source inductor, and a differential capacitor couped between the first and second source inductors.

The differential capacitor can be configured to resonate with the source inductors. The first and second input transistors can exhibit common mode noise and differential (mode) noise that are uncorrelated. By configuring the differential capacitor to resonate with the source inductors, the differential capacitor provides a high impedance and can be technically advantageous and beneficial by cancelling out the differential noise. Alternatively, the first and second source inductors can be magnetically coupled to one another to provide the desired differential noise cancellation.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols-sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHZ), a 5 GHz WLAN band (e.g., from 5180 to 5825 MHz), a Wi-Fi® 6E band (e.g., from 5925-7125 MHZ), and/or other Wi-Fi® bands (e.g., from 1875-5160 MHZ), wireless personal area network (WPAN) frequency bands such as the 2.4 GHz Bluetooth® band or other WPAN communications bands, cellular telephone frequency bands (e.g., bands from about 600 MHz to about 5 GHZ, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10-300 GHz, near-field communications frequency bands (e.g., at 13.56 MHZ), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

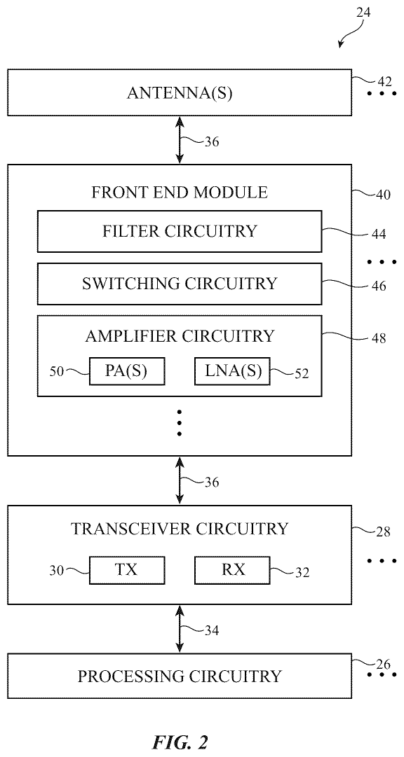

FIG. 2 is a diagram showing illustrative components within wireless circuitry 24. As shown in FIG. 2, wireless circuitry 24 may include processing circuitry such as processing circuitry 26, radio-frequency (RF) transceiver circuitry such as radio-frequency transceiver 28, radio-frequency front end circuitry such as radio-frequency front end module (FEM) 40, and antenna(s) 42. Processing circuitry 26 may include one or more baseband processor, application processor, general purpose processor, microprocessor, microcontroller, digital signal processor, host processor, application specific signal processing hardware, or other type of processor. Processing circuitry 26 may be coupled to transceiver 28 over path 34. Transceiver 28 may be coupled to antenna 42 via radio-frequency transmission line path 36. Radio-frequency front end module 40 may be disposed on radio-frequency transmission line path 36 between transceiver 28 and antenna 42.

In the example of FIG. 2, wireless circuitry 24 is illustrated as including only one instance of processing circuitry 26, a single transceiver 28, a single front end module 40, and a single antenna 42 for the sake of clarity. In general, wireless circuitry 24 may include any desired number of processing circuitry 26, any desired number of transceivers 28, any desired number of front end modules 40, and any desired number of antennas 42. Each processing circuitry 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processor 26 may provide transmit signals (e.g., digital or baseband signals) to transceiver 28 over path 34. Transceiver 28 may further include circuitry for converting the transmit (baseband) signals received from processor 26 into corresponding radio-frequency signals. For example, transceiver circuitry 28 may include mixer circuitry for up-converting (or modulating) the transmit (baseband) signals to radio frequencies prior to transmission over antenna 42. The example of FIG. 2 in which processor 26 communicates with transceiver 28 is merely illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front end module 40. Transceiver 28 may include circuitry such as receiver (RX) 32 for receiving signals from front end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processor 26 over path 34.

Front end module (FEM) 40 may include radio-frequency front end circuitry that operates on the radio-frequency signals conveyed (transmitted and/or received) over radio-frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processor 26 and/or portions of transceiver 28 (e.g., a host processor on transceiver 28) may form a part of control circuitry 14. Control circuitry 14 (e.g., portions of control circuitry 14 formed on processor 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHZ), a Wi-Fi® 6E band (e.g., from 5925-7125 MHZ), and/or other Wi-Fi® bands (e.g., from 1875-5160 MHZ), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHZ), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

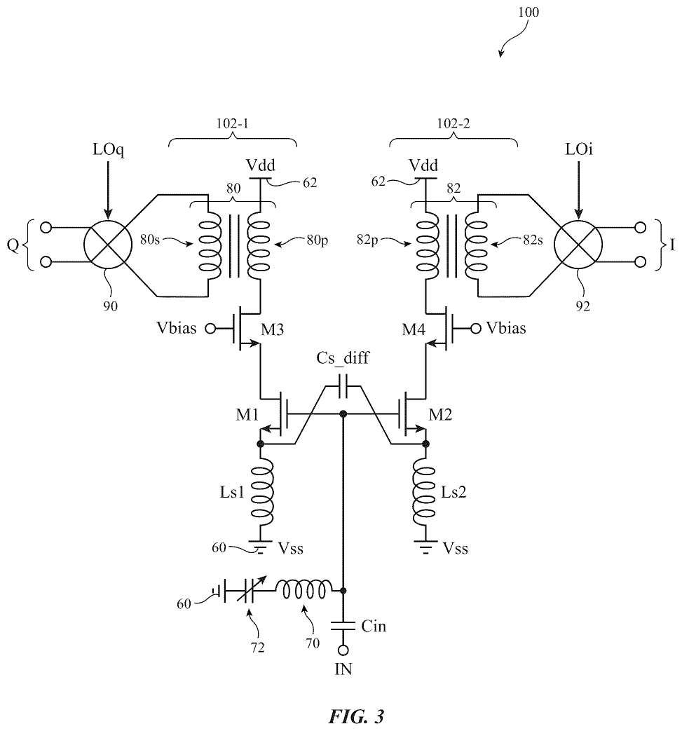

FIG. 3 is a diagram of illustrative amplifier circuitry 100 with improved noise cancelling capability in accordance with some embodiments. Amplifier circuitry 100 can represent one or more amplifier 52 of FIG. 2, one or more amplifier 50 of FIG. 2, and/or other amplifier. Embodiments in which amplifier circuitry 100 represents a radio-frequency receiving (low noise) amplifier is sometimes described herein as an example. As shown in FIG. 3, amplifier circuitry 100 can include a first amplifier 102-1 and a second amplifier 102-2.

First amplifier 102-1 may include a first input transistor M1, a first inductor Ls1, a first cascode transistor M3, and a first transformer 80. Transistors M1 and M3 can be n-type transistors (e.g., n-channel metal-oxide-semiconductor or NMOS transistors). First input transistor M1 may have a gate terminal coupled to an input terminal IN of amplifier circuitry 100, a drain terminal coupled to the first cascode transistor M3, and a source terminal coupled to the first inductor Ls1. The terms “source” and “drain” are sometimes used interchangeably when referring to current-conducting terminals of a metal-oxide-semiconductor transistor. The source and drain terminals are therefore sometimes referred to as “source-drain” terminals (e.g., a transistor has a gate terminal, a first source-drain terminal, and a second source-drain terminal).

First inductor Ls1 is coupled between input transistor M1 and a ground power supply line 60 (e.g., a ground power supply terminal on which ground power supply voltage Vss is provided). Inductor Ls1 being coupled to the source terminal of input transistor M1 is sometimes referred to as a source inductor or a source degeneration inductor. A source degeneration inductor can refer to and be defined herein as a series inductor that is coupled to a source terminal of an input transistors. A series capacitor Cin can be coupled at the input terminal IN. Inductor 70 and adjustable capacitor 72 can be coupled in series between the input terminal IN and ground line 60. Components Cin, 70, and 72 can optionally be configured as an adjustable input matching circuit (as an example). In general, the input matching network can include one or more capacitors, one or more inductors, and/or other passive or active components.

First cascode transistor M3 can have a source terminal coupled to input transistor M1, a gate terminal configured to receive a bias voltage Vbias, and a drain terminal coupled to transformer 80. Cascode transistor M3 is optional (e.g., transistor M3 can be omitted from amplifier 102-1). Transformer 80 is sometimes referred to as an output transformer or a load transformer. Transformer 80 can include a primary coil (winding) 80p and a secondary coil (winding) 80s. Primary coil 80p can have a first terminal coupled to cascode transistor M3 and a second terminal coupled to positive power supply line 62 (e.g., a positive power supply terminal on which positive power supply voltage Vdd is provided). Secondary coil 80s may be coupled to a corresponding mixer such as a quadrature (Q) mixer 90. Quadrature mixer 90 can be configured to receive an oscillating signal LOq and can be configured to output corresponding quadrature signals Q. Quadrature mixer 90 configured in this way can sometimes be referred to herein as a quadrature demodulator.

Second amplifier 102-2 may include a second input transistor M2, a second inductor Ls2, a second cascode transistor M4, and a second transformer 82. Transistors M2 and M4 can be n-type transistors (e.g., n-channel metal-oxide-semiconductor or NMOS transistors). Second input transistor M2 may have a gate terminal coupled to the input terminal IN of amplifier circuitry 100, a drain terminal coupled to the second cascode transistor M4, and a source terminal coupled to the second inductor Ls2. Second inductor Ls2 can be coupled between input transistor M2 and ground line 60. Inductor Ls2 being coupled to the source terminal of input transistor M2 is sometimes referred to as a source inductor or a source degeneration inductor. Inductors Ls1 and Ls2 can be identical in shape and can have the same inductance value.

Second cascode transistor M2 can have a source terminal coupled to input transistor M2, a gate terminal configured to receive bias voltage Vbias, and a drain terminal coupled to transformer 82. Cascode transistor M4 is optional (e.g., transistor M4 can be omitted from amplifier 102-2). Transformer 82 is sometimes referred to as an output transformer or a load transformer. Transformer 82 can include a primary coil (winding) 82p and a secondary coil (winding) 82s. Primary coil 82p can have a first terminal coupled to cascode transistor M4 and a second terminal coupled to positive power supply line 62. Secondary coil 82s may be coupled to a corresponding mixer such as an in-phase (I) mixer 92. Quadrature mixer 92 can be configured to receive an oscillating signal LOi and can be configured to output corresponding in-phase signals I. Oscillating signal LOi can be phase shifted (offset) by 90 degrees relative to signal LOq. In-phase mixer 92 configured in this way can sometimes be referred to herein as an in-phase demodulator.

If care is not taken, amplifier circuitry 100 can be subject to noise that could degrade its performance. In accordance with some embodiments, amplifier circuitry 100 can include a differential capacitor Cs_diff having a first terminal coupled to the source terminal of the first input transistor M1 and having a second terminal coupled to the source terminal of the second input transistor M2 (e.g., capacitor Cs_diff may be coupled between the source inductors Ls1 and Ls2). Assuming the components between amplifiers 102-1 and 102-2 are matched, any signal being amplified by amplifiers 102-1 and 102-2 should have the same amplitude and phase. Since these signals are common mode, the differential capacitor Cs_diff will appear invisible to the incoming radio-frequency signal, so the addition of capacitor Cs_diff will advantageously not affect the gain, input reflection coefficient, third-order intercept point, or other performance metrics of amplifier circuitry 100.

Conversely, capacitor Cs_diff will be visible to any differential signal being conveyed through amplifier circuitry 100. In accordance with some embodiments, capacitor Cs_diff can be configured to resonate with the differential source degeneration inductance. Assuming inductors Ls1 and Ls2 have the same inductance value Ls, capacitor Cs_diff and the two source inductors can be configured to resonate at a frequency that is a function of Cs_diff and 2*Ls. In practice, the input transistors M1 and M2 can exhibit noise that is uncorrelated with each other. The noise can include common mode noise and differential noise. Capacitor Cs_diff that resonates out with the source inductors can provide a high impedance at the source nodes of the input transistors and can be technically advantageous and beneficial to cancel out the differential noise associated with the input transistors M1 and M2 (e.g., by ensuring that any differential noise energy circulating through the source inductors Ls1 and Ls2 does not flow into the input transistors).

FIG. 7 is a plot of noise figure as a function of operating frequency. As shown in FIG. 7, amplifier circuitry 300 can exhibit a noise figure profile 300 with a minimum aligned to a frequency f*. Frequency f* may be equal to the resonant frequency that is a function of capacitance Cs_diff and 2*Ls. Configured as such, the noise figure of amplifier circuitry 100 can be minimized at frequency f*. If desired, the capacitance of differential capacitor Cs_diff can optionally be adjustable to tune or shift frequency f*. Thus, in some embodiments, capacitor Cs_diff can be a tunable capacitor, an adjustable capacitor, a programmable capacitor, a bank/array of switchable capacitors, or other types of adjustable capacitive circuit.

The source impedance of amplifier circuitry 100 looking down from the source terminals of the input transistors M1 and M2 can be expressed as follows:

$$Zcm = j ω Ls / 2 \qquad ( 1 )$$

$$Zdm = ( j ω * 2 Ls ) / ( 1 - {ω}^{{2}^{*}} 2 Ls * Cs\_diff ) \qquad ( 2 )$$

where Zcm in equation 1 represents the common mode source impedance of the input transistors, Zdm in equation 2 represents the differential mode source impedance of the input transistors, Ls represents the inductance of each of the source inductors Ls1 and Ls2, and Cs_diff represent the capacitance of the differential capacitor. Since only Zdm is a function of Cs_diff (while Zcm is not a function of Cs_diff), this allows Zcm and Zdm to be controlled independently, offering improved flexibility in the design of amplifier circuitry 100. Capacitor Cs_diff is thus sometimes referred to herein as a noise cancellation circuit or component.

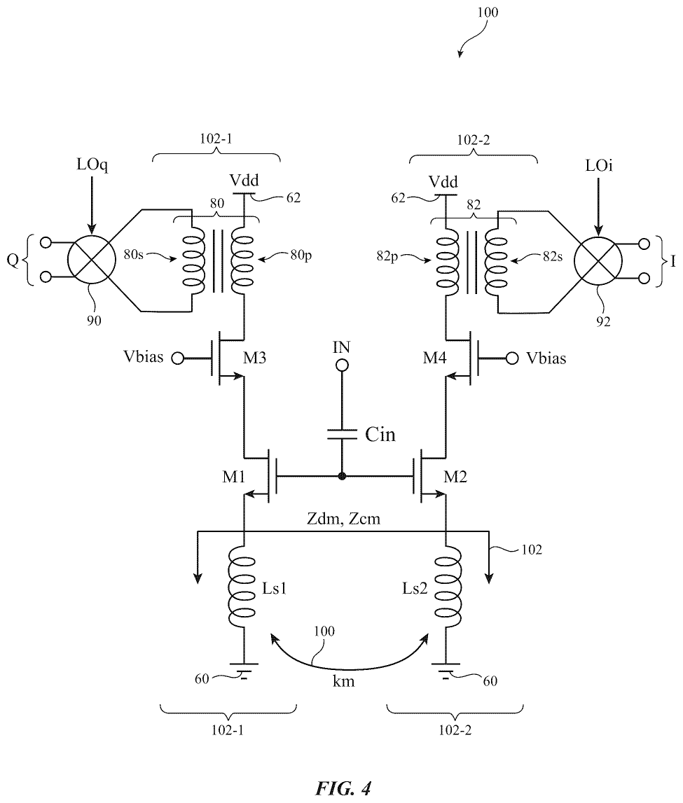

The embodiment of FIG. 3 in which amplifier circuitry 100 is provided with differential capacitor Cs_diff being configured to reduce the noise of circuitry 100 is exemplary. FIG. 4 shows another embodiment of amplifier circuitry 100 in which the first source inductor Ls1 is magnetically coupled to the second source inductor Ls2 (see, e.g., as illustrated by magnetic coupling arrow 100). Unlike the embodiment of FIG. 3, amplifier circuitry 100 of FIG. 4 does not include a differential capacitor Cs_diff. The remaining structure of amplifier circuitry 100 of FIG. 4 may be identical or similar to that already described in connection with FIG. 3 and need not be reiterated in detail in order to avoid obscuring the present embodiment.

As shown in FIG. 4, the first source inductor Ls1 may be magnetically or inductively coupled to the second source inductor Ls2 with a coupling coefficient km. The source impedance of amplifier circuitry 100 looking down from the source terminals of the input transistors M1 and M2 can be expressed as follows:

$$Zcm = ( 1 + k m ) * j ω Ls / 2 \qquad ( 3 )$$

$$Zdm = 2 ( 1 - k m ) * j ω Ls \qquad ( 4 )$$

where Zcm in equation 3 represents the common mode source impedance of the input transistors, Zdm in equation 4 represents the differential mode source impedance of the input transistors, and Ls represents the inductance of each of the source inductors Ls1 and Ls2. Since both Zcm and Zdm are a function of coupling coefficient km, the magnetic coupling between the two source inductors can also be tuned to control Zcm and Zdm independently.

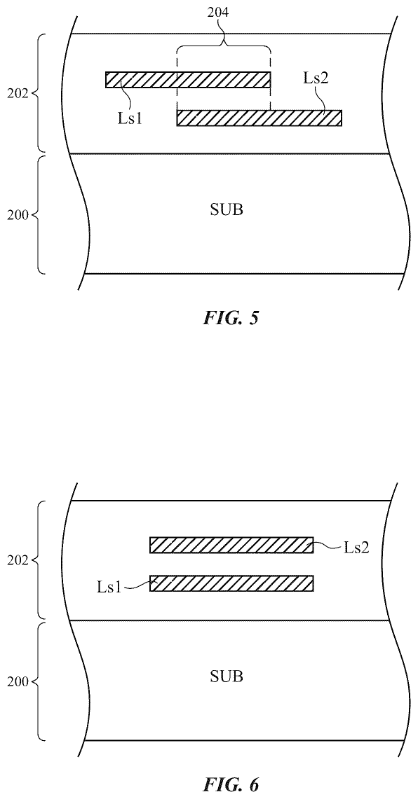

The amount of magnetic coupling (e.g., the value of coupling coefficient km) between inductors Ls1 and Ls2 can be tuned by the amount of overlap between the two inductors. FIG. 5 is a side view showing partially overlapping source inductors Ls1 and Ls2 in accordance with some embodiments. As shown in FIG. 5, an interconnect stack such as interconnect stack 202 can be formed on semiconductor substrate 200. Semiconductor substrate 200 can be a p-type (p doped) semiconductor substrate, as an example). Interconnect stack 202 may include alternating routing layers and via layers. Each routing layer can include conductive (metal) routing paths formed in a layer of dielectric material. Each via layer can include conductive (metal) vias formed in a layer of dielectric material. Interconnect stack 202 is therefore sometimes referred to as a dielectric stack (e.g., an interconnect stack having conductive routing paths formed within dielectric material such as silicon dioxide). The conductive routing path and via structures can be formed using copper, aluminum, tungsten, titanium, gold, silver, nickel, a metal alloy, a combination of metals, and/or other types of conductive material. The metal routing and via structures can form an electrical network for interconnecting together various components within an integrated circuit die or chip.

In the example of FIG. 5, inductor Ls1 can be formed in a first metal routing layer, whereas inductor Ls2 is formed in a second metal routing layer. Inductors Ls1 and Ls2 can each be implemented as a coil having windings with any number of turns (e.g., only one turn, a partial turn, two or more turns, three or more turns, four or more turns, etc.), any winding pattern (e.g., spiral winding pattern, figure-8 winding pattern, etc.), and any suitable shape (e.g., circular, octagonal, rectangular, square, hexagonal, etc.). Inductors Ls1 and Ls2 can be partially overlapped (see partially overlapping portion 204). The example of FIG. 5 in which inductors Ls1 and Ls2 are each shown as having only a single layer of conductive material is illustrative. If desired, Ls1 and Ls2 can each be implemented as a coil structure having two or more layers or three of more layers of conductive material. In other embodiments, Ls2 and be formed above Ls1 in the dielectric stack 202.

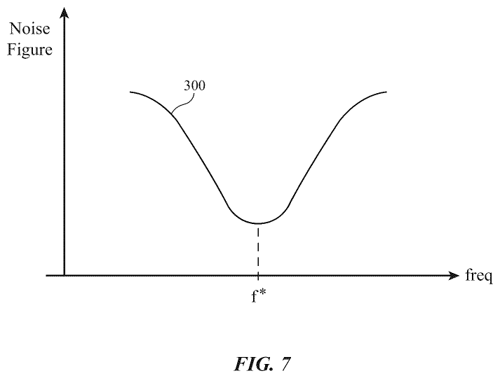

The partial overlapping arrangement of FIG. 5 can provide a relatively lower amount of magnetic coupling. In accordance with another embodiment, the source inductors Ls1 and Ls2 can be entirely overlapped (see, e.g., FIG. 6). As shown in FIG. 6, inductors Ls1 and Ls2 can be horizontally aligned such that the footprint of inductor Ls1 coincides with the footprint of inductor Ls2. In general, inductors Ls1 and Ls2 can each be implemented as a coil having windings with any number of turns, any winding pattern, and any suitable shape. The example of FIG. 6 in which inductors Ls1 and Ls2 are each shown as having only a single layer of conductive material is illustrative. If desired, Ls1 and Ls2 can each be implemented as a coil structure having two or more layers or three of more layers of conductive material. In other embodiments, Ls2 and be formed above Ls1 in the dielectric stack 202. The completely overlapping arrangement of FIG. 6 can provide a high amount of magnetic coupling for elevated noise cancelling capability.

The methods and operations described above in connection with FIGS. 1-4 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. Circuitry comprising:
a first input transistor having a gate terminal coupled to an input terminal;
a second input transistor having a gate terminal coupled to the input terminal;
a first inductor coupled to a source terminal of the first input transistor; and
a capacitor having a first terminal coupled to the source terminal of the first input transistor and having a second terminal coupled to a source terminal of the second input transistor.

2. The circuitry of claim 1, further comprising:
a second inductor coupled between the source terminal of the second input transistor and a power supply line.

3. The circuitry of claim 2, further comprising:
an input matching network coupled to the input terminal.

4. The circuitry of claim 2, further comprising:
a first transformer having a first primary coil coupled to the first input transistor.

5. The circuitry of claim 4, further comprising:
a second transformer having a second primary coil coupled to the second input transistor.

6. The circuitry of claim 5, further comprising:
a first cascode transistor coupled between the first primary coil and the first input transistor; and
a second cascode transistor coupled between the second primary coil and the second input transistor.

7. The circuitry of claim 5, further comprising:
a first mixer coupled to a first secondary coil of the first transformer; and
a second mixer coupled to a second secondary coil of the second transformer.

8. The circuitry of claim 7, wherein:
the first mixer is configured to receive a first oscillating signal; and
the second mixer is configured to receive a second oscillating signal different than the first oscillating signal, wherein the first oscillating signal and the second oscillating signal are offset in phase by 90 degrees.

9. The circuitry of claim 2, wherein the capacitor is configured to resonate with the first and second inductors.

10. The circuitry of claim 2, wherein the first and second input transistors comprise:
a differential mode source impedance that is based on an inductance of the first inductor or the second inductor and a capacitance of the capacitor; and
a common mode source impedance that is based on the inductance of the first inductor or the second inductor and not based on the capacitance of the capacitor.

11. Circuitry comprising:
a first amplifier having a first source degeneration inductor;
a second amplifier having a second source degeneration inductor; and
a noise cancellation circuit coupled between the first and second source degeneration inductors.

12. The circuitry of claim 11, wherein:
the first amplifier comprises a first input transistor coupled in series with the first source degeneration inductor;
the first input transistor has a gate terminal coupled to an input terminal;
the second amplifier comprises a second input transistor coupled in series with the second source degeneration inductor; and
the second input transistor has a gate terminal coupled to the input terminal.

13. The circuitry of claim 12, wherein the noise cancellation circuit comprises a capacitor coupled across a source terminal of the first input transistor and a source terminal of the second input transistor.

14. The circuitry of claim 12, wherein:
the first amplifier further comprises a first transformer coupled to the first input transistor; and
the second amplifier further comprises a second transformer coupled to the second input transistor.

15. The circuitry of claim 14, further comprising:
a first demodulator coupled to the first transformer; and
a second demodulator coupled to the second transformer.

16. Circuitry comprising:
a first amplifier having a first input;
a second amplifier having a second input shorted to the first input; and
a differential noise cancellation circuit coupled between the first and second amplifiers.

17. The circuitry of claim 16, wherein the differential noise cancellation circuit comprises a capacitor.

18. The circuitry of claim 16, wherein the first amplifier comprises:
a first input transistor; and
a first inductor coupled to a source terminal of the first input transistor.

19. The circuitry of claim 18, wherein the second amplifier comprises:
a second input transistor; and
a second inductor coupled to a source terminal of the second input transistor.

20. The circuitry of claim 19, wherein the differential noise cancellation circuit comprises:
a first terminal coupled to a first node disposed between the first input transistor and the first inductor; and
a second terminal coupled to a second node disposed between the second input transistor and the second inductor.
